(19) United States
(12) Patent Application Publication
(10) Pub. No.: US 2025/0167151 A1
(43) Pub. Date: May 22, 2025

(54) SEMICONDUCTOR PACKAGE

(71) Applicant: Samsung Electronics Co., Ltd., Suwon-si (KR)

(72) Inventors: Chonghee LEE, Suwon-si (KR); Yunrae CHO, Suwon-si (KR)

(73) Assignee: Samsung Electronics Co., Ltd., Suwon-si (KR)

(21) Appl. No.: 18/679,992

(22) Filed: May 31, 2024

(30) Foreign Application Priority Data
Nov. 20, 2023 (KR) 10-2023-0160305

(51) Int. Cl. H01L 23/00

(52) U.S. Cl. CPC H01L 24/14; H01L 24/16; H01L 24/32; H01L 24/73; H01L 2224/14177; H01L 2224/14517; H01L 2224/16227; H01L 2224/32225; H01L 2224/73204

(57) ABSTRACT

A semiconductor package includes a wiring board including a wiring pattern, a solder resist layer on a top surface of the wiring board and defining an opening that exposes the wiring pattern, solder resist patterns arranged in the opening, and a semiconductor chip electrically connected to the wiring pattern of the wiring board and mounted on the wiring board. The solder resist patterns are arranged under a first edge of one side of the semiconductor chip.

### CROSS-REFERENCE TO RELATED APPLICATION

This application is based on and claims priority under 35 U.S.C. § 119 to Korean Patent Application No. 10-2023-0160305, filed on Nov. 20, 2023 in the Korean Intellectual Property Office, the disclosure of which is incorporated by reference herein in its entirety.

### BACKGROUND

The inventive concepts relate to semiconductor packages, and more particularly, to semiconductor packages including a molding layer.

A semiconductor package electrically connects a semiconductor chip onto a top surface of a wiring board by using internal bumps and is electrically connected to an external device through a plurality of external connection terminals formed on a bottom surface of the wiring board. The semiconductor package is completed by molding the semiconductor chip electrically connected onto the wiring board into a molding layer.

### SUMMARY

The inventive concepts relate to semiconductor packages with improved performance and reliability.

The problems to be solved by the inventive concepts are not limited to the above-mentioned problems, and other problems not mentioned will be clearly understood by those skilled in the art from the following description.

Example embodiments of the inventive concepts provide a semiconductor package that includes a wiring board including a wiring pattern; a solder resist layer on a top surface of the wiring board, the solder resist pattern defining an opening that exposes the wiring pattern; solder resist patterns arranged in the opening; and a semiconductor chip electrically connected to the wiring pattern of the wiring board and mounted on the wiring board and the solder resist patterns are arranged under a first edge of one side of the semiconductor chip.

Example embodiments of the inventive concepts further provide a semiconductor package that includes a wiring board; a semiconductor chip on a top surface of the wiring board and electrically connected to the wiring board; a molding layer between the wiring board and the semiconductor chip and molding the wiring board and the semiconductor chip; and solder resist patterns surrounded by the molding layer under the semiconductor chip and the solder resist patterns are arranged under one side of the semiconductor chip.

Example embodiments of the inventive concepts still further provide a semiconductor package that includes a wiring board including a wiring pattern; a solder resist layer on a top surface of the wiring board, the solder resist layer defining an opening that exposes the wiring pattern; a semiconductor chip electrically connected to the wiring pattern of the wiring board and mounted on the wiring board; a molding layer in the opening between the wiring board and the semiconductor chip and molding the wiring board and the semiconductor chip; solder resist patterns arranged in the opening between the wiring board and the semiconductor chip and surrounded by the molding layer; and a plurality of signal bumps surrounded by the molding layer between the wiring board and the semiconductor chip, the plurality of signal bumps electrically connecting the wiring board and the semiconductor chip. The plurality of signal bumps are arranged in a line under a center of the semiconductor chip along a first horizontal direction, and the solder resist patterns are arranged in a line along the first horizontal direction under a first edge of the semiconductor chip extending in the first horizontal direction.

### BRIEF DESCRIPTION OF THE DRAWINGS

Some example embodiments of the inventive concepts will be more clearly understood from the following detailed description taken in conjunction with the accompanying drawings in which:

FIG. 1 is a plan view of a semiconductor package according to some example embodiments;

FIG. 2 is a plan view illustrating some components of the semiconductor package according to some example embodiments;

FIG. 3 is a plan view illustrating some components of the semiconductor package according to some example embodiments;

FIG. 4 is a cross-sectional view taken along the line X1-X1 of FIG. 1;

FIG. 5 is a cross-sectional view taken along the line X2-X2 of FIG. 1;

FIG. 6 is a cross-sectional view taken along the line Y1-Y1 of FIG. 1;

FIG. 7 is a cross-sectional view of a semiconductor package according to some example embodiments;

FIGS. 8 and 9 are plan views of a semiconductor package according to some example embodiments;

FIGS. 10, 11, 12, 13, 14, 15, 16, 17 and 18 are plan views of semiconductor packages according to some example embodiments; and

FIGS. 19A, 19B, 20A, 20B, 21A, 21B, 22A, and 22B are intermediate stage diagrams for explaining a method of manufacturing a semiconductor package according to some example embodiments.

### DETAILED DESCRIPTION

Hereinafter, some example embodiments of the inventive concepts will be described in detail with reference to the accompanying drawings. Some of the following example embodiments may be implemented as taken alone, or one or more of the following example embodiments may be implemented in combination. Therefore, the inventive concepts are not limited to any one embodiment.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%. For example

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

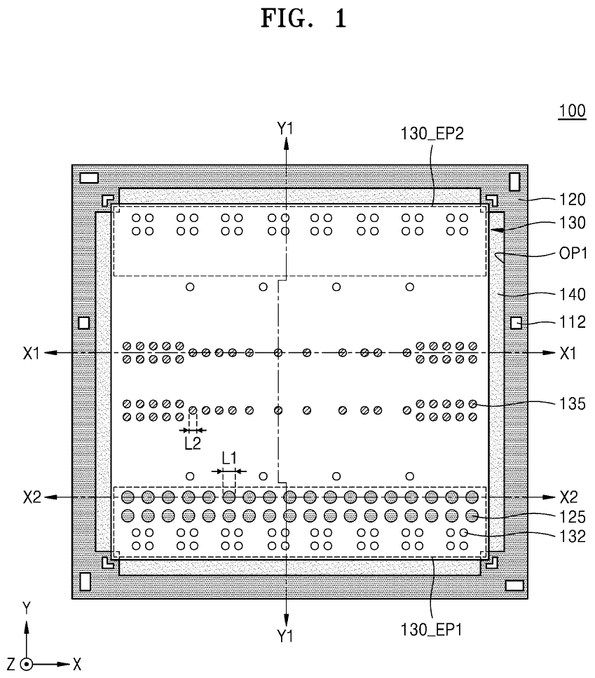

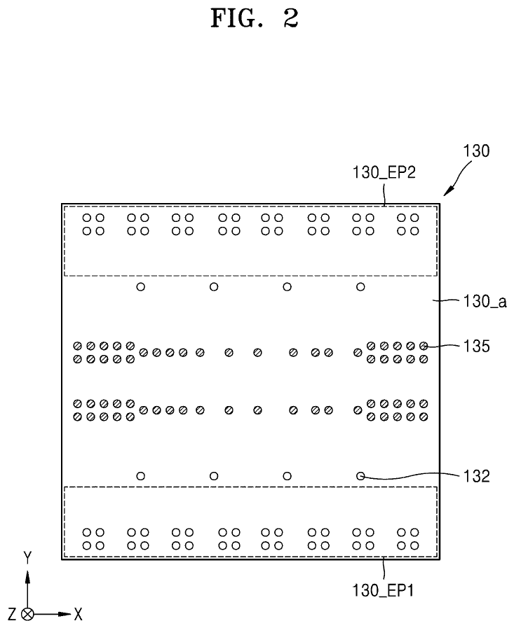

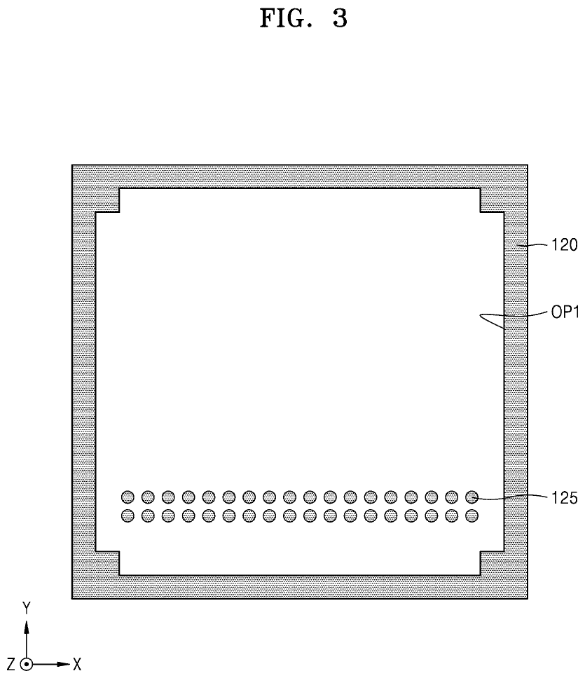

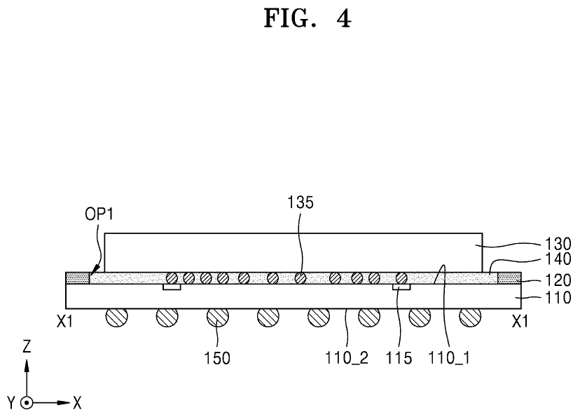

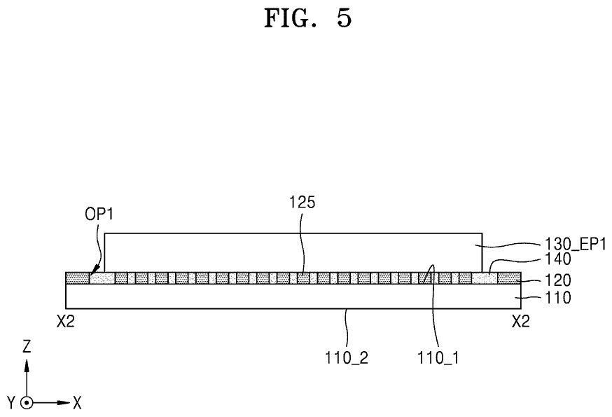

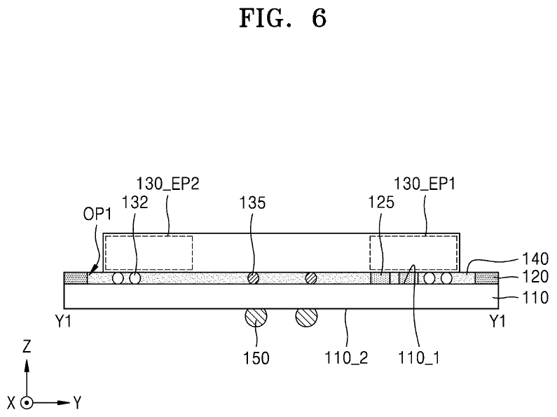

FIG. 1 is a plan view of a semiconductor package 100 according to some example embodiments. FIG. 2 is a plan view illustrating some components of the semiconductor package 100 according to some example embodiments. FIG. 3 is a plan view illustrating some components of the semiconductor package 100 according to some example embodiments. For example, FIG. 2 is a plan view illustrating a semiconductor chip 130 of the semiconductor package 100. For example, FIG. 3 is a plan view illustrating a solder resist layer 120 and solder resist patterns 125 of the semiconductor package 100 of FIG. 3. FIG. 4 is a cross-sectional view taken along the line X1-X1 of FIG. 1. FIG. 5 is a cross-sectional view taken along the line X2-X2 of FIG. 1. FIG. 6 is a cross-sectional view taken along the line Y1-Y1 of FIG. 1.

Referring to FIGS. 1 to 6, the semiconductor package 100 may include a wiring board 110, the solder resist layer 120, the solder resist patterns 125, the semiconductor chip 130, a plurality of signal bumps 135, a molding layer 140, and a plurality of external connection terminals 150.

In some example embodiments, the wiring board 110 may include a printed circuit board (PCB). The wiring board 110 may have a top surface 110_1 and a bottom surface 110_2 opposite to each other. The wiring board 110 may include, for example, a core layer, an upper wiring layer on a top surface of the core layer, and a lower wiring layer on a bottom surface of the core layer. The upper wiring layer may include an upper wiring pattern 115 to be electrically connected to the semiconductor chip 130 (e.g., see FIG. 4). The lower wiring layer may include a lower wiring pattern to be electrically connected to the plurality of external connection terminals 150. In some example embodiments, the wiring board 110 may further include an alignment pattern 112 to facilitate mounting the semiconductor chip 130 near an edge thereof.

For example, the core layer may include at least one of prepreg resin, thermosetting epoxy resin, thermoplastic epoxy resin, and resin including a filler. For example, the upper wiring layer and the lower wiring layer may include a metal, for example, copper (Cu) or aluminum (Al).

In some example embodiments, the solder resist layer 120 may include an opening OP1 exposing a portion of the wiring board 110. For example, the solder resist layer 120 may include and/or define the opening OP1 exposing the wiring pattern 115 of the wiring board 110.

In some example embodiments, the solder resist patterns 125 may be arranged in the opening OP1 of the solder resist layer 120. For example, the solder resist patterns 125 may be arranged in the opening OP1 of the solder resist layer 120 on the wiring board 110. The solder resist patterns 125 may be arranged in the opening OP1 of the solder resist layer 120 at a position where the plurality of signal bumps 135 and a plurality of dummy bumps 132 are not arranged. For example, the solder resist patterns 125 may not overlap the plurality of signal bumps 135 and the plurality of dummy bumps 132.

In some example embodiments, the semiconductor chip 130 may be arranged on the top surface 110_1 of the wiring board 110. The semiconductor chip 130 may be electrically connected to the upper wiring pattern formed on the top surface 110_1 of the wiring board 110. The semiconductor chip 130 may be electrically connected to the upper wiring pattern 115 by the plurality of signal bumps 135 arranged on an active surface 130_a of the semiconductor chip 130.

In some example embodiments, the semiconductor chip 130 may include individual devices. The individual devices may include various microelectronics devices, for example, a metal-oxide-semiconductor field effect transistor (MOSFET) such as a complementary metal-insulator-semiconductor (CMOS) transistor, an image sensor such as a system large scale integration (LSI) or a CMOS imaging sensor (CIS), a micro-electro-mechanical system (MEMS), an active device, and a passive device.

In some example embodiments, the semiconductor chip 130 may include a logic chip, a power management integrated circuit (PMIC) chip, or a memory chip. In some example embodiments, the logic chip may include a memory controller chip, a central processing unit (CPU) chip, a graphics processing unit (GPU) chip, or an application processor (AP) chip.

In some example embodiments, the memory chip may include a dynamic random access memory (DRAM) chip, a static random access memory (SRAM) chip, a flash memory chip, an electrically erasable and programmable read-only memory (EEPROM) chip, a phase-change random access memory (PRAM) chip, a magnetic random access memory (MRAM) chip, or a resistive random access memory (RRAM) chip.

In some example embodiments, the plurality of signal bumps 135 may electrically connect the wiring board 110 to the semiconductor chip 130 between the wiring board 110 and the semiconductor chip 130. In some example embodiments, the plurality of signal bumps 135 may be arranged under the center of the semiconductor chip 130. For example, the plurality of signal bumps 135 may be arranged under the center of the semiconductor chip 130 in a second horizontal direction (Y direction). In some example embodiments, the plurality of signal bumps 135 may be arranged in a line in a first horizontal direction (X direction) under the semiconductor chip 130.

In some other example embodiments, unlike as shown in the figures, the plurality of signal bumps 135 may be arranged under the center of the semiconductor chip 130 in the first horizontal direction (X direction). In some example embodiments, the plurality of signal bumps 135 may be arranged in a line in the second horizontal direction (Y direction) under the semiconductor chip 130.

In some example embodiments, a size of each of the plurality of signal bumps 135 may be less than a size of each of the solder resist patterns 125. For example, a horizontal size of each of the plurality of signal bumps 135 may be less than a horizontal size of each of the solder resist patterns 125. For example, a width L2 of each of the plurality of signal bumps 135 in the first horizontal direction (X direction) may be less than a width L1 of each of the solder resist patterns 125 in the first horizontal direction (X direction). For example, the width L1 of each of the solder resist patterns 125 in the first horizontal direction (X direction) may be about 200 μm to about 600 μm. For example, the width L2 of each of the plurality of signal bumps 135 in the first horizontal direction (X direction) may be about 200 μm or less.

For example, the plurality of signal bumps 135 may include at least one metal or metal alloy of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C).

Hereinafter, the relationship between the solder resist patterns 125 and the semiconductor chip 130 and the plurality of signal bumps 135 will be described.

In some example embodiments, the solder resist patterns 125 may be arranged in a line in the first horizontal direction (X direction) under the semiconductor chip 130. In some example embodiments, the solder resist patterns 125 may be arranged under one side of the semiconductor chip 130. For example, the solder resist patterns 125 may be arranged on one side of the semiconductor chip 130 in the second horizontal direction (Y direction). For example, in some example embodiments the solder resist patterns 125 may not be arranged on the other side of the semiconductor chip 130. For example, the solder resist patterns 125 may be asymmetrically arranged in the second horizontal direction (Y direction).

In some example embodiments, the solder resist patterns 125 may be arranged on one side of the plurality of signal bumps 135. For example, the solder resist patterns 125 may be arranged in a line in the first horizontal direction (X direction) on one side of the plurality of signal bumps 135 in the second horizontal direction (Y direction). For example, in some example embodiments the solder resist patterns 125 may not be arranged on the other side of the plurality of signal bumps 135. For example, the solder resist patterns 125 may be asymmetrically arranged in the second horizontal direction (Y direction) based on the plurality of signal bumps 135.

In some other example embodiments, unlike as shown in the figures, when the plurality of signal bumps 135 are arranged in a line in the second horizontal direction (Y direction) under the center of the semiconductor chip 130 in the first horizontal direction (X direction), the solder resist patterns 125 may be arranged in a line in the second horizontal direction (Y direction) under the semiconductor chip 130. In some other example embodiments, the solder resist patterns 125 may be arranged on one side of the semiconductor chip 130 in the first horizontal direction (X direction) and may not be arranged on the other side. In some other example embodiments, the solder resist patterns 125 may be arranged on one side of the plurality of signal bumps 135 in the second horizontal direction (Y direction) and may not be arranged on the other side. For example, the solder resist patterns 125 may be asymmetrically arranged in the first horizontal direction (X direction).

For example, the solder resist patterns 125 may be arranged under a first edge 130_EP1 of the semiconductor chip 130. The first edge 130_EP1 of the semiconductor chip 130 may include an edge on one side of the semiconductor chip 130 in the second horizontal direction (Y direction) and may extend in the first horizontal direction (X direction). The semiconductor chip 130 may further include a second edge 130_EP2 facing the first edge 130_EP1. The second edge 130_EP2 of the semiconductor chip 130 may include an edge on the other side of the semiconductor chip 130 in the second horizontal direction (Y direction) and may extend in the first horizontal direction (X direction). In some example embodiments, the solder resist patterns 125 may not be arranged under the second edge 130_EP2 of the semiconductor chip 130. For example, the solder resist patterns 125 may be arranged only under an edge (for example, the first edge 130_EP1) on one side of the semiconductor chip 130.

In some example embodiments, the semiconductor package 100 may further include the plurality of dummy bumps 132 that are not electrically connected to the wiring board 110 between the wiring board 110 and the semiconductor chip 130. The plurality of dummy bumps 132 may support the semiconductor chip 130. In some example embodiments, the plurality of dummy bumps 132 may be arranged at positions where the plurality of signal bumps 135 are not formed. For example, the plurality of dummy bumps 132 may be arranged under the edge of the semiconductor chip 130 except for the center of the semiconductor chip 130. For example, the plurality of dummy bumps 132 may be arranged under the first edge 130_EP1 and the second edge 130_EP2 of the semiconductor chip 130. The position and arrangement of the plurality of dummy bumps 132 are not limited to the illustration.

In some example embodiments, a molding layer 140 filling a space between the wiring board 110 and the semiconductor chip 130 may be arranged. The molding layer 140 may surround the solder resist patterns 125, the plurality of signal bumps 135, and the plurality of dummy bumps 132 between the wiring board 110 and the semiconductor chip 130. For example, the molding layer 140 may mold the semiconductor chip 130 on the wiring board 110. The molding layer 140 may mold the semiconductor chip 130, the solder resist patterns 125, the plurality of signal bumps 135, and the plurality of dummy bumps 132 on the wiring board 110.

For example, the molding layer 140 may include a silicon-based material, a thermosetting material, a thermoplastic material, or an ultraviolet (UV)-treated material. For example, the molding layer 140 may include polymer such as resin, for example, an epoxy molding compound (EMC).

In some example embodiments, the plurality of external connection terminals 150 may be arranged on the bottom surface 110_2 of the wiring board 110. The plurality of external connection terminals 150 may be electrically connected to the lower wiring pattern of the wiring board 110. For example, the plurality of external connection terminals 150 may include at least one metal or metal alloy of Cu, Al, Ni, Ag, Au, Pt, Sn, Pb, Ti, Cr, Pd, In, Zn, and C.

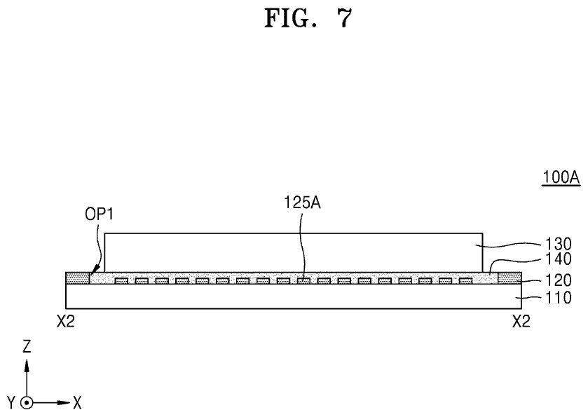

FIG. 7 is a cross-sectional view of a semiconductor package 100A according to some example embodiments.

Referring to FIG. 7 and FIG. 1, the semiconductor package 100A may include a wiring board 110, the solder resist layer 120, the solder resist patterns 125A, a semiconductor chip 130, a plurality of signal bumps 135, a molding layer 140, and a plurality of external connection terminals 150.

Hereinafter, the wiring board 110, the solder resist layer 120, the solder resist patterns 125A, the semiconductor chip 130, the plurality of signal bumps 135, the molding layer 140, and the plurality of external connection terminals 150 of the semiconductor package 100A may be described with reference to the components of the semiconductor package 100 described with reference to FIGS. 1 to 6.

In some example embodiments, a vertical thickness of each of the solder resist patterns 125A of the semiconductor package 100A may be less than a vertical thickness of each of the solder resist patterns 125 of the semiconductor package 100. In some example embodiments, the molding layer 140 may surround the solder resist patterns 125A. In some example embodiments, the molding layer 140 may include a portion arranged on the solder resist patterns 125A. For example, the molding layer 140 may include a portion arranged between the solder resist patterns 125A and the semiconductor chip 130.

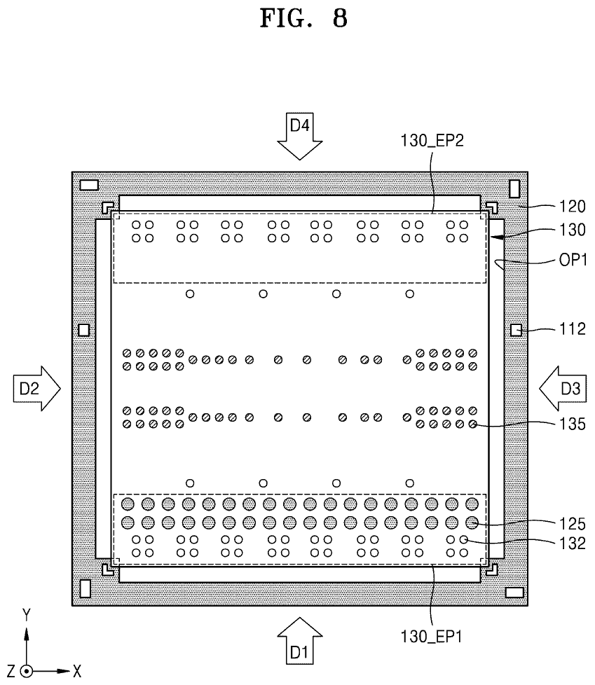

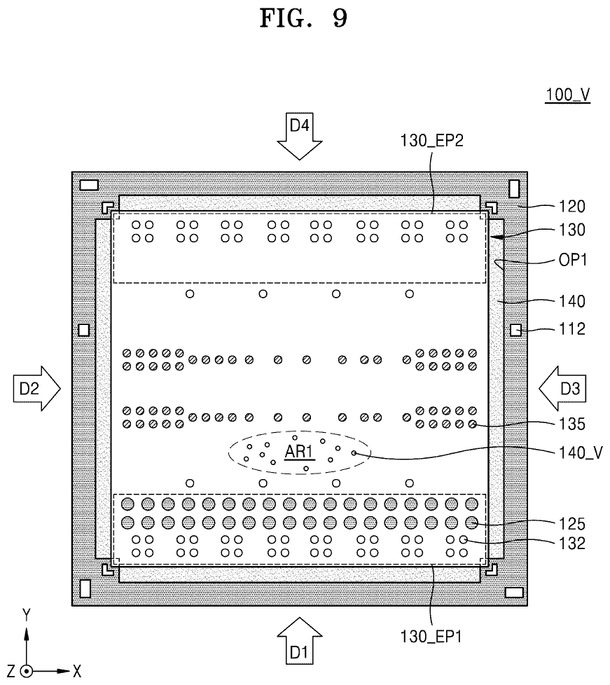

FIGS. 8 and 9 are cross-sectional views of a semiconductor package 100_V according to some example embodiments. For example, FIGS. 8 and 9 are cross-sectional views illustrating processes of manufacturing a molding layer 140 of the semiconductor package 100_V.

Referring to FIGS. 8 and 9, the molding layer 140 may be formed by a molded underfill (MUF) process. For example, when the molding layer 140 includes an EMC, the EMC may be provided in a direction facing one surface of a semiconductor chip 130. For example, the EMC may be provided in first to fourth directions D1 to D4 facing four surfaces of the semiconductor chip 130, respectively. For example, the EMC may be provided in the first to fourth directions D1 to D4 and may flow under the semiconductor chip 130. The EMC under the semiconductor chip 130 may form the molding layer 140 by filling a space between a wiring board 110 and the semiconductor chip 130 in an opening OP1, after passing a space among solder resist patterns 125, a plurality of signal bumps 135, and a plurality of dummy bumps 132.

In some example embodiments, when the EMC is provided in the first to fourth directions D1 to D4 facing the four surfaces of the semiconductor chip 130, the EMC may flow under the semiconductor chip 130 at the same flow rate in the first to fourth directions D1 to D4. In this case, when the solder resist patterns 125 are arranged under one side of the semiconductor chip 130 in the semiconductor package 100_V, the flow rate of the EMC flowing through the solder resist patterns 125 may decrease. For example, when the solder resist patterns 125 are arranged under the first edge 130_EP1 of the semiconductor chip 130, the flow rate of the EMC flowing in the first direction D1 may be reduced by the solder resist patterns 125. Therefore, as illustrated in FIG. 9, the EMC flowing in the first to fourth directions D1 to D4 may overlap at a position apart from the center of the semiconductor chip 130 under the semiconductor chip 130. For example, the EMC flowing in the first to fourth directions D1 to D4 may overlap in a first region AR1 adjacent to the first edge 130_EP1 of the semiconductor chip 130. Accordingly, in some example embodiments, the molding layer 140 may further include one or more voids 140_V trapped in the first region AR1.

In some example embodiments, the one or more voids 140_V of the semiconductor package 100_V may be trapped at a position apart from the center of the semiconductor chip 130 under the semiconductor chip 130. For example, the one or more voids 140_V may not overlap the plurality of signal bumps 135 arranged under the center of the semiconductor chip 130. Unlike in the inventive concepts, when the one or more voids 140_V are trapped under the center of the semiconductor chip 130, the one or more voids 140_V may overlap the plurality of signal bumps 135 or may be formed around the plurality of signal bumps 135 to cause defects. Therefore, when the solder resist patterns 125 are arranged under one side of the semiconductor chip 130 according to some example embodiments, the defects may be limited and/or prevented. That is, according to some example embodiments, the semiconductor package 100_V with improved performance and reliability may be provided.

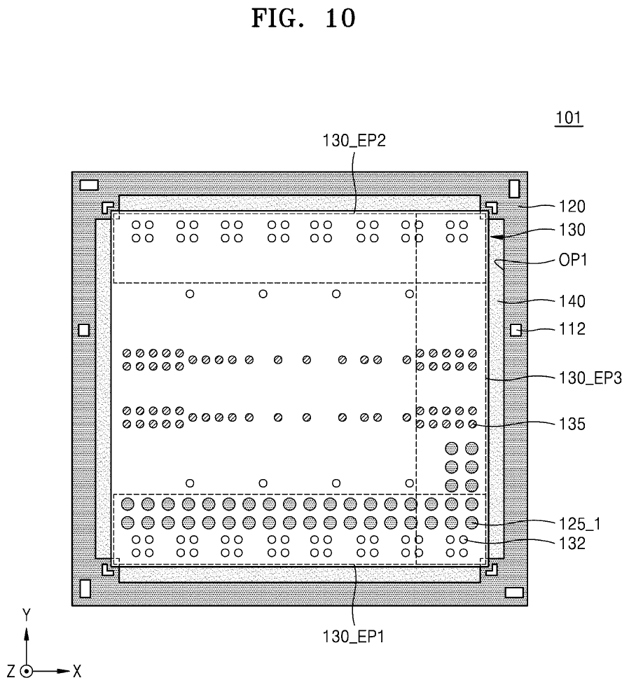

FIGS. 10 to 18 are plan views of semiconductor packages 101 to 109 according to some example embodiments. Hereinafter, the difference from the semiconductor package 100 described with reference to FIGS. 1 to 6 will be mainly described.

Referring to FIG. 10, the semiconductor package 101 may include solder resist patterns 125_1 surrounded by a molding layer 140 between a wiring board 110 and a semiconductor chip 130.

In some example embodiments, the solder resist patterns 125_1 may be arranged under a first edge 130_EP1 of the semiconductor chip 130 and may not be arranged under a second edge 130_EP2 of the semiconductor chip 130. The solder resist patterns 125_1 may be further arranged under a third edge 130_EP3 of the semiconductor chip 130. The third edge 130_EP3 of the semiconductor chip 130 may extend in a direction intersecting with the first edge 130_EP1 of the semiconductor chip 130. For example, the third edge 130_EP3 of the semiconductor chip 130 may extend in the second horizontal direction (Y direction).

In some example embodiments, under the third edge 130_EP3, the solder resist patterns 125_1 may be further arranged on one side of a plurality of signal bumps 135. For example, under the third edge 130_EP3, the solder resist patterns 125_1 may be further arranged on one side of the plurality of signal bumps 135 adjacent to the first edge 130_EP1. For example, under the first edge 130_EP1 and the third edge 130_EP3, the solder resist patterns 125_1 may be arranged only on one side of the plurality of signal bumps 135.

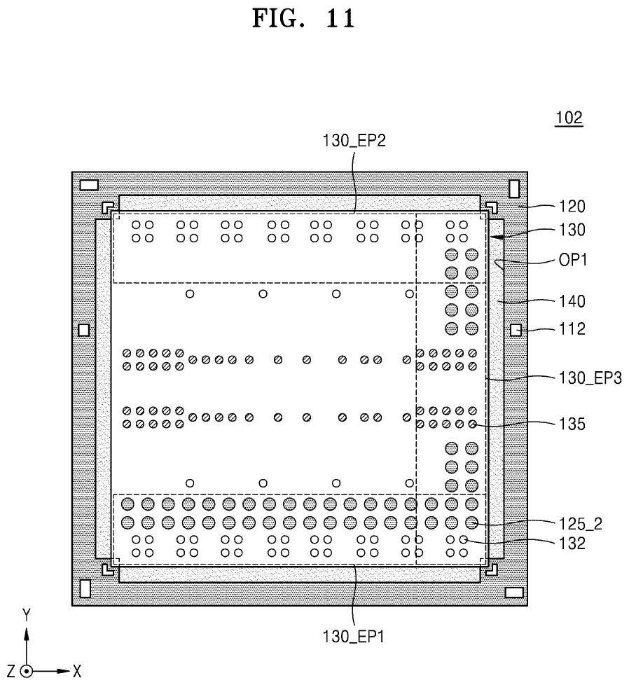

Referring to FIG. 11, the semiconductor package 102 may include solder resist patterns 125_2 surrounded by a molding layer 140 between a wiring board 110 and a semiconductor chip 130.

In some example embodiments, the solder resist patterns 125_2 may be arranged under a first edge 130_EP1 of the semiconductor chip 130 and may not be arranged under a part of a second edge 130_EP2. The solder resist patterns 125_2 may be further arranged under a third edge 130_EP3 of the semiconductor chip 130.

In some example embodiments, under the third edge 130_EP3, the solder resist patterns 125_2 may be further arranged on both sides of a plurality of signal bumps 135. For example, under the third edge 130_EP3, the solder resist patterns 125_1 may be further arranged on one side adjacent to the first edge 130_EP1 and one side adjacent to the second edge 130_EP2.

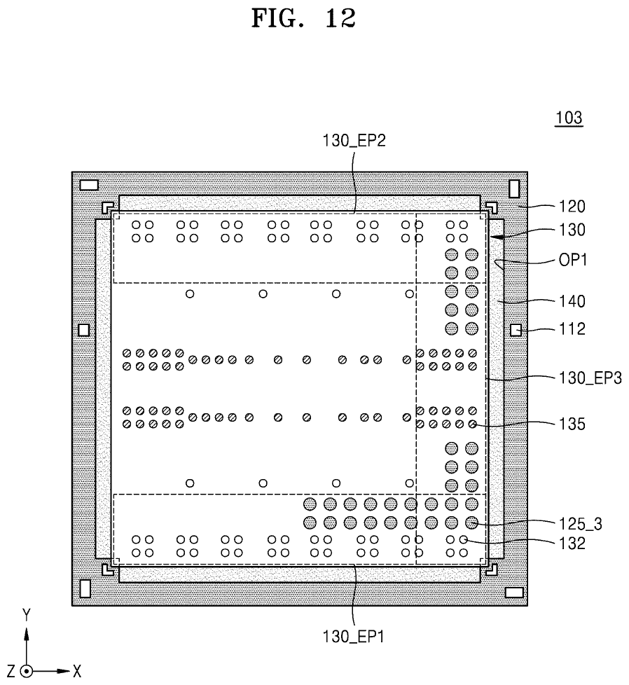

Referring to FIG. 12, the semiconductor package 103 may include solder resist patterns 125_3 surrounded by a molding layer 140 between a wiring board 110 and a semiconductor chip 130.

In some example embodiments, the solder resist patterns 125_3 may be arranged under a first edge 130_EP1 of the semiconductor chip 130 and may not be arranged under a part of a second edge 130_EP2. The solder resist patterns 125_3 may be further arranged under a third edge 130_EP3 of the semiconductor chip 130.

In some example embodiments, the solder resist patterns 125_3 may be arranged under a part of the first edge 130_EP1 of the semiconductor chip 130. For example, under the first edge 130_EP1, the solder resist patterns 125_3 may be further arranged under a part adjacent to the third edge 130_EP3. For example, the solder resist patterns 125_3 may be arranged under a part of the first edge 130_EP1 adjacent to the third edge 130_EP and under the third edge 130_EP3.

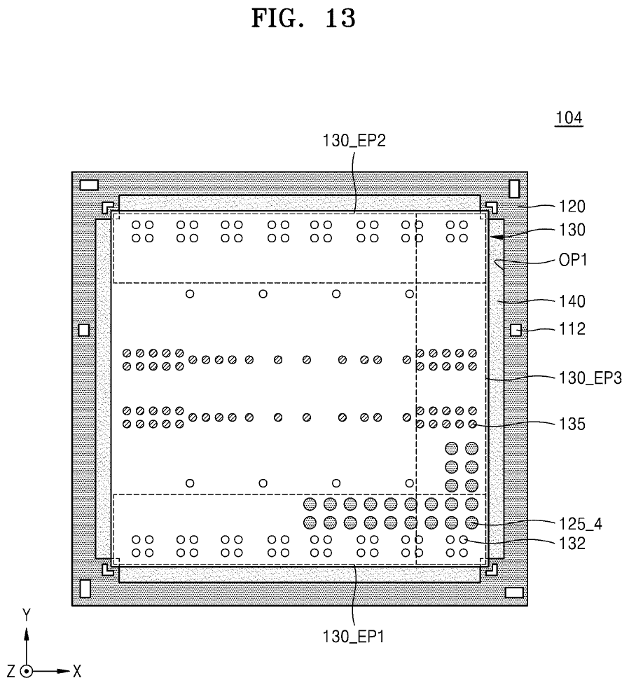

Referring to FIG. 13, the semiconductor package 104 may include solder resist patterns 125_4 surrounded by a molding layer 140 between a wiring board 110 and a semiconductor chip 130.

In some example embodiments, the solder resist patterns 125_4 may be arranged under a first edge 130_EP1 of the semiconductor chip 130 and may not be arranged under a second edge 130_EP2. The solder resist patterns 125_4 may be further arranged under a third edge 130_EP3 of the semiconductor chip 130.

In some example embodiments, the solder resist patterns 125_4 may be arranged under a part of the first edge 130_EP1 of the semiconductor chip 130. For example, under the first edge 130_EP1, the solder resist patterns 125_4 may be further arranged in a part adjacent to the third edge 130_EP3. In some example embodiments, under the third edge 130_EP3, the solder resist patterns 125_4 may be further arranged on one side of a plurality of signal bumps 135. For example, under the third edge 130_EP3, the solder resist patterns 125_4 may be further arranged on one side of the plurality of signal bumps 135 adjacent to the first edge 130_EP1.

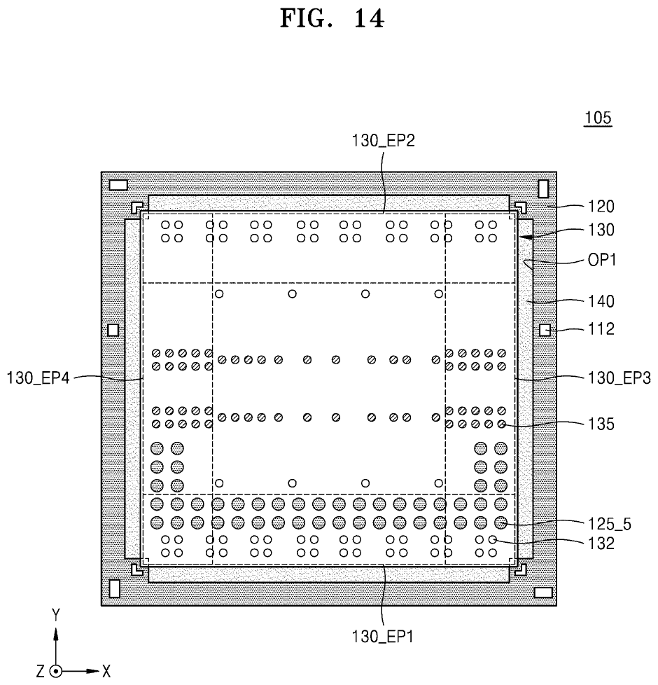

Referring to FIG. 14, the semiconductor package 105 may include solder resist patterns 125_5 surrounded by a molding layer 140 between a wiring board 110 and a semiconductor chip 130.

In some example embodiments, the solder resist patterns 125_5 may be arranged under a first edge 130_EP1 of the semiconductor chip 130 and may not be arranged under a second edge 130_EP2. The solder resist patterns 125_5 may be further arranged under a third edge 130_EP3 and a fourth edge 130_EP4 facing each other in the semiconductor chip 130. The fourth edge 130_EP4 may extend in a direction intersecting with the first edge 130_EP1 of the semiconductor chip 130. For example, the fourth edge 130_EP4 may extend in the second horizontal direction (Y direction).

In some example embodiments, under the third edge 130_EP3, the solder resist patterns 125_5 may be further arranged on one side of a plurality of signal bumps 135. For example, under the third edge 130_EP3, the solder resist patterns 125_5 may be further arranged on one side of the plurality of signal bumps 135 adjacent to the first edge 130_EP1.

In some example embodiments, under the fourth edge 130_EP4, the solder resist patterns 125_5 may be further arranged on one side of the plurality of signal bumps 135. For example, under the fourth edge 130_EP4, the solder resist patterns 125_5 may be further arranged on one side of the plurality of signal bumps 135 adjacent to the first edge 130_EP1.

For example, under the first edge 130_EP1, the third edge 130_EP3, and the fourth edge 130_EP4, the solder resist patterns 125_5 may be arranged only on one side of the plurality of signal bumps 135.

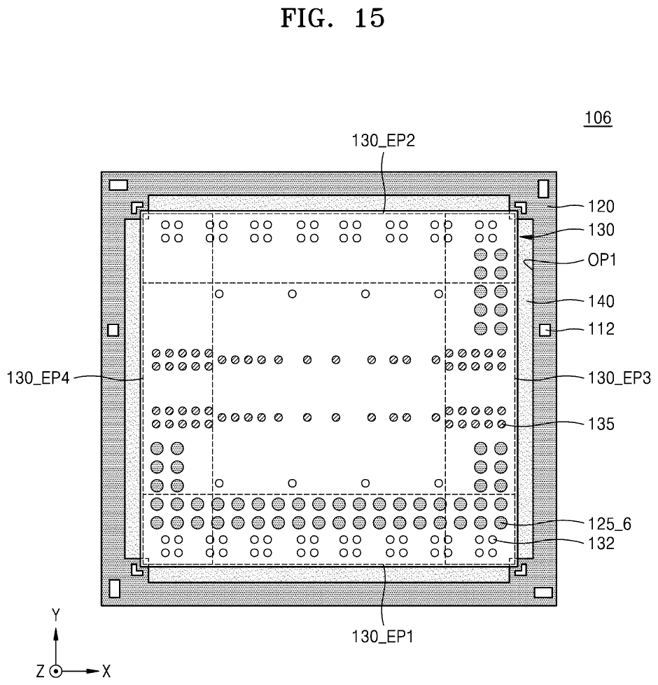

Referring to FIG. 15, the semiconductor package 106 may include solder resist patterns 125_6 surrounded by a molding layer 140 between a wiring board 110 and a semiconductor chip 130.

In some example embodiments, the solder resist patterns 125_6 may be arranged under a first edge 130_EP1 of the semiconductor chip 130 and may not be arranged under a part of a second edge 130_EP2. The solder resist patterns 125_6 may be further arranged under a third edge 130_EP3 and a fourth edge 130_EP4 facing each other in the semiconductor chip 130.

In some example embodiments, under the third edge 130_EP3, the solder resist patterns 125_6 may be further arranged on both sides of a plurality of signal bumps 135. For example, under the third edge 130_EP3, the solder resist patterns 125_6 may be further arranged on one side adjacent to the first edge 130_EP1 and one side adjacent to the second edge 130_EP2.

In some example embodiments, under the fourth edge 130_EP4, the solder resist patterns 125_6 may be further arranged on one side of the plurality of signal bumps 135. For example, under the fourth edge 130_EP4, the solder resist patterns 125_6 may be further arranged on one side of the plurality of signal bumps 135 adjacent to the first edge 130_EP1.

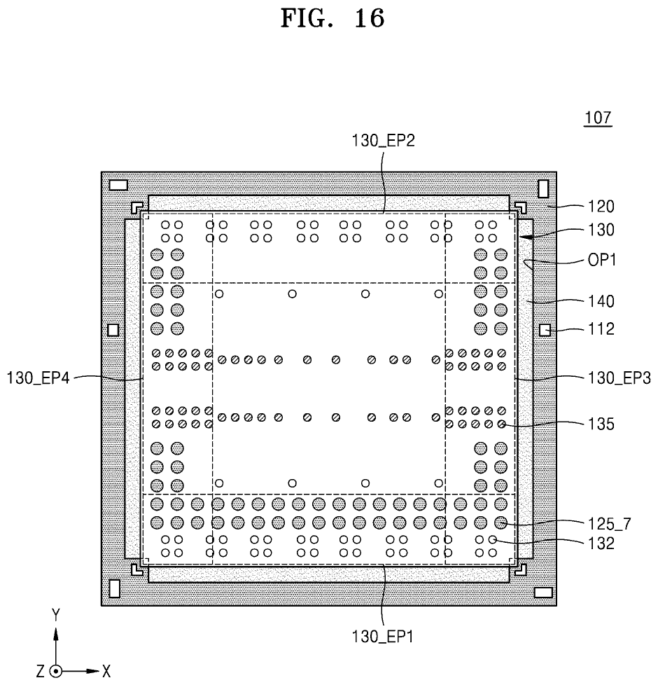

Referring to FIG. 16, the semiconductor package 107 may include solder resist patterns 125_7 surrounded by a molding layer 140 between a wiring board 110 and a semiconductor chip 130.

In some example embodiments, the solder resist patterns 125_7 may be arranged under a first edge 130_EP1 of the semiconductor chip 130 and may not be arranged under a part of a second edge 130_EP2. The solder resist patterns 125_7 may be further arranged under a third edge 130_EP3 and a fourth edge 130_EP4 facing each other in the semiconductor chip 130.

In some example embodiments, under the third edge 130_EP3 and the fourth edge 130_EP4, the solder resist patterns 125_7 may be further arranged on both sides of a plurality of signal bumps 135. For example, under the third edge 130_EP3 and the fourth edge 130_EP4, the solder resist patterns 125_7 may be further arranged on one side adjacent to the first edge 130_EP1 and one side adjacent to the second edge 130_EP2.

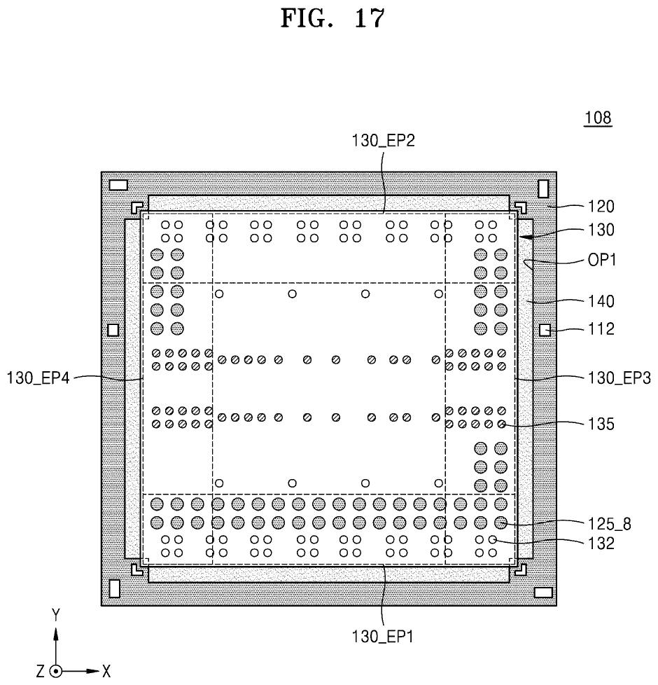

Referring to FIG. 17, the semiconductor package 108 may include solder resist patterns 125_8 surrounded by a molding layer 140 between a wiring board 110 and a semiconductor chip 130.

In some example embodiments, the solder resist patterns 125_8 may be arranged under a first edge 130_EP1 of the semiconductor chip 130 and may not be arranged under a part of a second edge 130_EP2. The solder resist patterns 125_8 may be further arranged under a third edge 130_EP3 and a fourth edge 130_EP4 facing each other in the semiconductor chip 130.

In some example embodiments, under the third edge 130_EP3, the solder resist patterns 125_8 may be further arranged on both sides of a plurality of signal bumps 135. For example, under the third edge 130_EP3, the solder resist patterns 125_8 may be further arranged on one side adjacent to the first edge 130_EP1 and one side adjacent to the second edge 130_EP2.

In some example embodiments, under the fourth edge 130_EP4, the solder resist patterns 125_8 may be further arranged on one side of the plurality of signal bumps 135. For example, under the fourth edge 130_EP4, the solder resist patterns 125_8 may be further arranged on one side of the plurality of signal bumps 135 adjacent to the second edge 130_EP2.

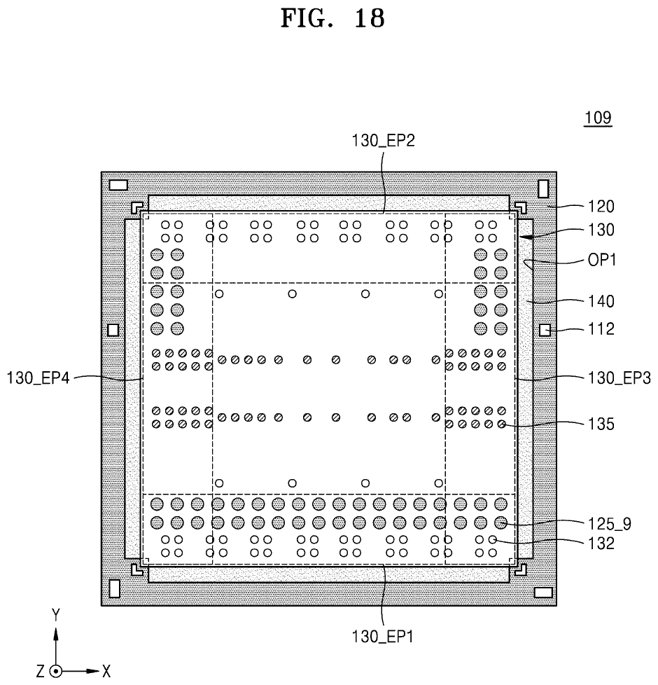

Referring to FIG. 18, the semiconductor package 109 may include solder resist patterns 125_9 surrounded by a molding layer 140 between a wiring board 110 and a semiconductor chip 130.

In some example embodiments, the solder resist patterns 125_9 may be arranged under a first edge 130_EP1 of the semiconductor chip 130 and may not be arranged under a part of a second edge 130_EP2. The solder resist patterns 125_9 may be further arranged under a third edge 130_EP3 and a fourth edge 130_EP4 facing each other in the semiconductor chip 130.

In some example embodiments, under the third edge 130_EP3, the solder resist patterns 125_9 may be further arranged on one side of a plurality of signal bumps 135. For example, under the third edge 130_EP3, the solder resist patterns 125_9 may be further arranged on one side of the plurality of signal bumps 135 adjacent to the second edge 130_EP2.

In some example embodiments, under the fourth edge 130_EP4, the solder resist patterns 125_9 may be further arranged on one side of the plurality of signal bumps 135. For example, under the fourth edge 130_EP4, the solder resist patterns 125_9 may be further arranged on one side of the plurality of signal bumps 135 adjacent to the second edge 130_EP2.

In example embodiments described with respect to FIGS. 1-18, the solder resist patterns 125_1 through 125_9 are respectively arranged so that one or more voids 140_V such as shown in FIG. 9 may be trapped at a position apart from the center of the semiconductor chip 130 under the semiconductor chip 130 and may not overlap the plurality of signal bumps 135. Therefore, when the solder resist patterns 125_1 through 125_9 are arranged as respectively shown in FIGS. 10-18, defects may be limited and/or prevented and semiconductor packages with improved performance and reliability may be provided.

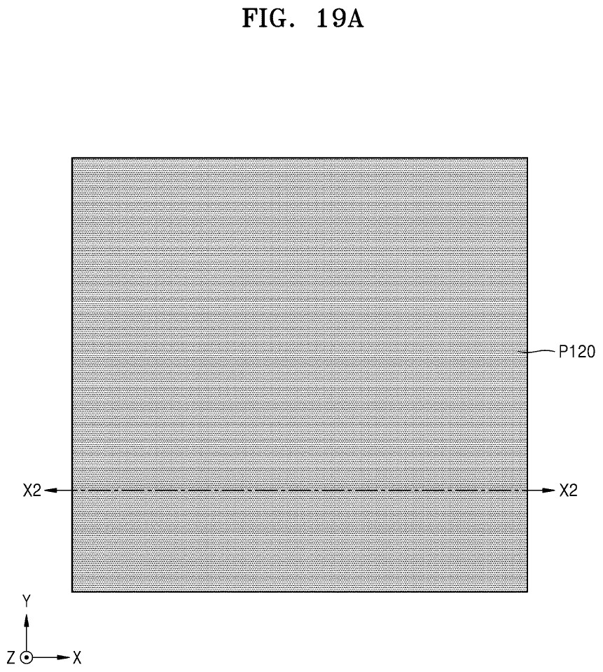

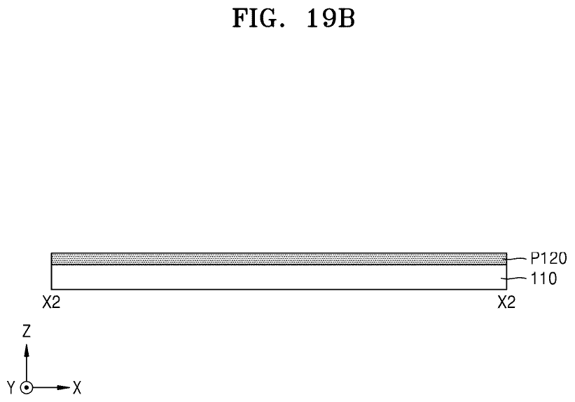

FIGS. 19A, 19B, 20A, 20B, 21A, 21B, 22A, and 22B are intermediate stage diagrams illustrating a method of manufacturing a semiconductor package 100 according to some example embodiments. For example, FIGS. 19A, 20A, 21A, and 22A are plan views of intermediate stages of a method of manufacturing the semiconductor package 100. FIGS. 19B, 20B, 21B, and 22B are cross-sectional views taken along X2-X2 of FIGS. 19A, 20A, 21A, and 22A, respectively.

Referring to FIGS. 19A and 19B, a pre-solder resist layer P120 covering the top surface of the wiring board 110 may be formed on the wiring board 110.

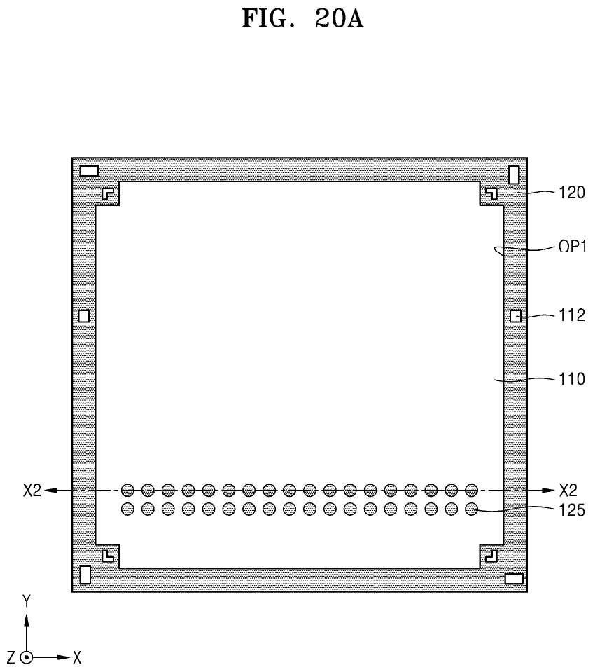

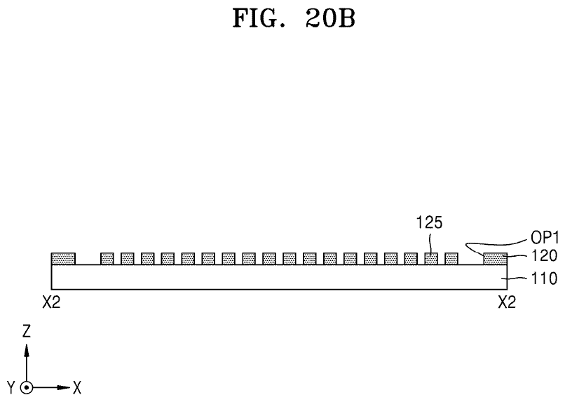

Referring to FIGS. 20A and 20B, a part of the pre-solder resist layer P120 may be removed to form the solder resist layer 120. For example, a part of the pre-solder resist layer P120 may be removed to form the solder resist layer 120 having (and/or defining) the opening OP1 exposing a part of the wiring board 110.

The solder resist patterns 125 may be formed in the opening OP1. Forming the solder resist patterns 125 may include removing a part of the pre-solder resist layer P120 to leave a necessary portion.

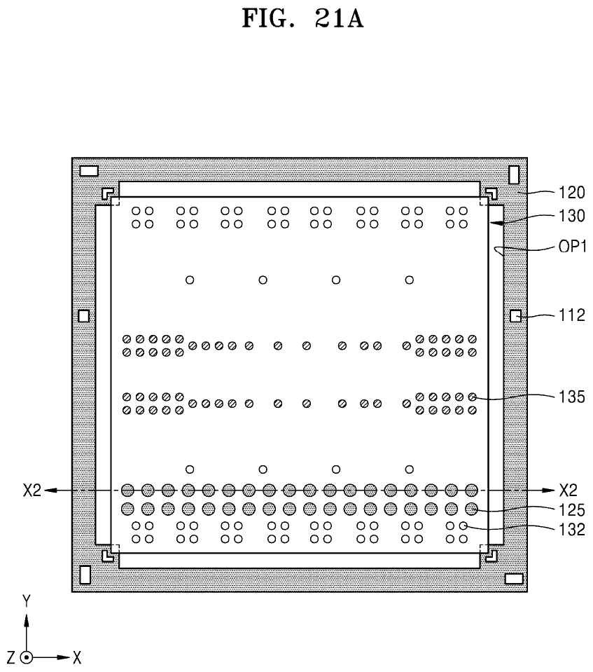

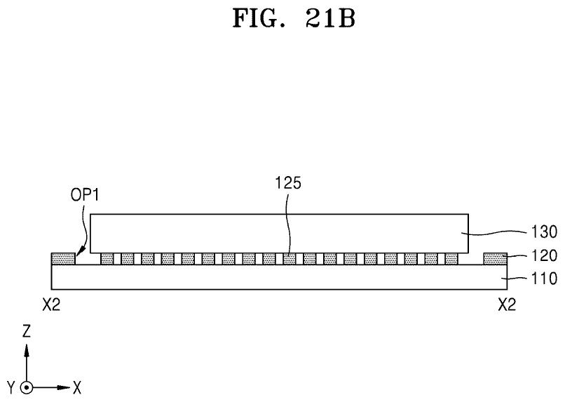

Referring to FIGS. 21A and 21B, the semiconductor chip 130 may be mounted on the wiring board 110. For example, the semiconductor chip 130 may be mounted on the wiring board 110 to be electrically connected to the wiring pattern of the wiring board 110. In some example embodiments, the semiconductor chip 130 may be arranged on the solder resist patterns 125.

In some example embodiments, the plurality of dummy bumps 132 and the plurality of signal bumps 135 on the active surface of the semiconductor chip 130 may be arranged on the wiring board 110. For example, the plurality of dummy bumps 132 and the plurality of signal bumps 135 may be arranged in the opening OP1 of the solder resist layer 120.

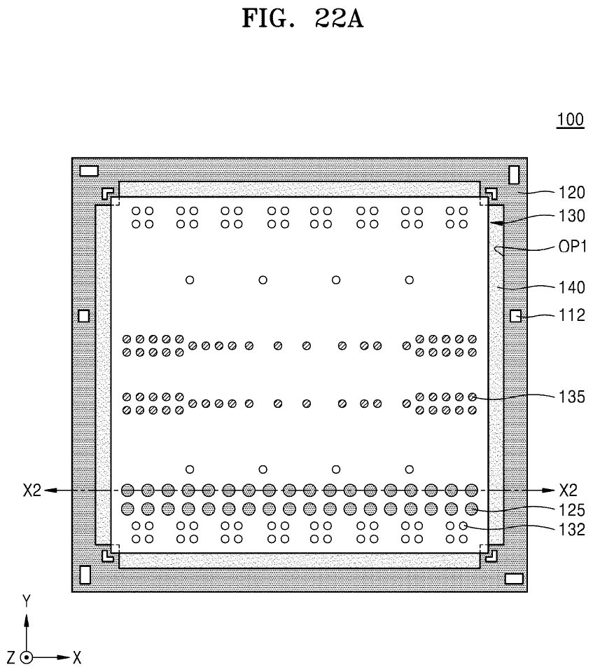

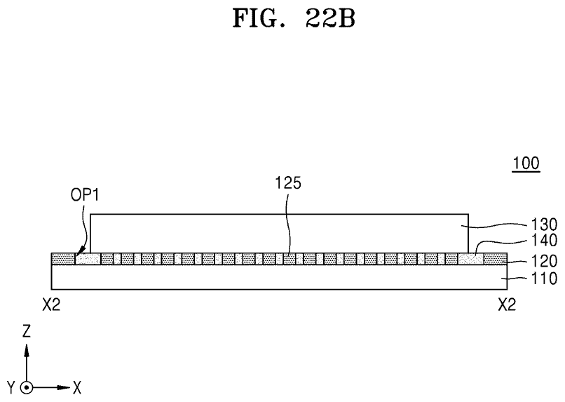

Referring to FIGS. 22A and 22B, the molding layer 140 may be formed to mold the semiconductor chip 130. As described with reference to FIGS. 7 and 8, the molding layer 140 may pass a space among the solder resist layer 120, the plurality of dummy bumps 132, and the plurality of signal bumps 135 to fill the space between the wiring board 110 and the semiconductor chip 130.

In some other example embodiments, as described with reference to FIGS. 8 and 9, in the process of forming the molding layer 140, the one or more voids 140_V (refer to FIG. 9) may be trapped and arranged between the plurality of signal bumps 135 and the solder resist patterns 125.

Subsequently, the plurality of external connection terminals 150 (refer to FIG. 4) may be attached onto the bottom surface of the wiring board 110 to form the semiconductor package 100.

While the inventive concepts have been particularly shown and described with reference to some example embodiments thereof, it will be understood that various changes in form and details may be made therein without departing from the spirit and scope of the following claims.

What is claimed is:

1. A semiconductor package comprising:
a wiring board including a wiring pattern;
a solder resist layer on a top surface of the wiring board, the solder resist layer defining an opening that exposes the wiring pattern;
solder resist patterns arranged in the opening; and
a semiconductor chip electrically connected to the wiring pattern of the wiring board and mounted on the wiring board, wherein the solder resist patterns are arranged under a first edge of one side of the semiconductor chip.

2. The semiconductor package of claim 1, further comprising a plurality of signal bumps between the wiring board and the semiconductor chip, and the plurality of signal bumps connecting the wiring pattern to the semiconductor chip, wherein the plurality of signal bumps are arranged under a center of the semiconductor chip.

3. The semiconductor package of claim 2, further comprising a plurality of dummy bumps that are not electrically connected to the wiring board between the wiring board and the semiconductor chip.

4. The semiconductor package of claim 2, wherein a size of each of the solder resist patterns is greater than a size of each of the plurality of signal bumps.

5. The semiconductor package of claim 2, wherein the plurality of signal bumps are arranged along a line in a first horizontal direction.

6. The semiconductor package of claim 1, wherein the solder resist patterns are not arranged under a second edge of the semiconductor chip facing the first edge of the semiconductor chip.

7. The semiconductor package of claim 1, wherein the semiconductor chip further comprises a second edge extending in a direction intersecting with the first edge, and
wherein the solder resist patterns further comprise a portion arranged under the second edge.

8. The semiconductor package of claim 1, further comprising a molding layer filling a space between the wiring board and the semiconductor chip in the opening.

9. A semiconductor package comprising:
a wiring board;
a semiconductor chip on a top surface of the wiring board and electrically connected to the wiring board;
a molding layer between the wiring board and the semiconductor chip and molding the wiring board and the semiconductor chip; and
solder resist patterns surrounded by the molding layer under the semiconductor chip, wherein the solder resist patterns are arranged under one side of the semiconductor chip.

10. The semiconductor package of claim 9, further comprising a plurality of signal bumps surrounded by the molding layer between the wiring board and the semiconductor chip, the plurality of signal bumps electrically connecting the wiring board and the semiconductor chip.

11. The semiconductor package of claim 10, wherein the plurality of signal bumps are arranged in a line under a center of the semiconductor chip along a first horizontal direction.

12. The semiconductor package of claim 11, wherein the solder resist patterns are arranged in a line along the first horizontal direction under a first edge of the semiconductor chip extending in the first horizontal direction.

13. The semiconductor package of claim 10, wherein the solder resist patterns are arranged on one side of the plurality of signal bumps and are not arranged on an other side.

14. The semiconductor package of claim 10, wherein the molding layer comprises one or more voids arranged between the plurality of signal bumps and the solder resist patterns.

15. The semiconductor package of claim 9, further comprising a plurality of dummy bumps that are not electrically connected to the wiring board, wherein the solder resist patterns do not overlap the plurality of dummy bumps in a vertical direction.

16. The semiconductor package of claim 9, wherein the molding layer further comprises a portion arranged between the solder resist patterns and the semiconductor chip.

17. A semiconductor package comprising:
a wiring board including a wiring pattern;
a solder resist layer on a top surface of the wiring board, the solder resist layer defining an opening that exposes the wiring pattern;
a semiconductor chip electrically connected to the wiring pattern of the wiring board and mounted on the wiring board;
a molding layer in the opening between the wiring board and the semiconductor chip and molding the wiring board and the semiconductor chip;
solder resist patterns arranged in the opening between the wiring board and the semiconductor chip and surrounded by the molding layer; and
a plurality of signal bumps surrounded by the molding layer between the wiring board and the semiconductor chip, the plurality of signal bumps electrically connecting the wiring board and the semiconductor chip, wherein the plurality of signal bumps are arranged in a line under a center of the semiconductor chip along a first horizontal direction, and
wherein the solder resist patterns are arranged in a line along the first horizontal direction under a first edge of the semiconductor chip extending in the first horizontal direction.

18. The semiconductor package of claim 17, wherein the solder resist patterns are arranged on one side of the plurality of signal bumps, and
wherein the solder resist patterns are not arranged on an other side of the plurality of signal bumps.

19. The semiconductor package of claim 17, wherein the semiconductor chip further comprises a second edge extending in a second horizontal direction intersecting with the first horizontal direction, and
wherein the solder resist patterns further comprise a portion arranged under the second edge.

20. The semiconductor package of claim 19, wherein the solder resist patterns are arranged along a line under the second edge in the second horizontal direction.
